(19) United States
(12) Patent Application Publication
(10) Pub. No.: US 2006/0222026 A1
(43) Pub. Date: Oct. 5, 2006

(54) Semiconductor laser device and manufacturing method therefor

(75) Inventor: Kazuhiko Wada, Yamatokooriyama-shi (JP)

Correspondence Address: MORRISON & FOERSTER LLP, 1650 TYSONS BOULEVARD, SUITE 300, MCLEAN, VA, 22102, US

(73) Assignee: SHARP KABUSHIKI KAISHA, Osaka-shi (JP)

(21) Appl. No.: 11/391,370

(22) Filed: Mar. 29, 2006

(30) Foreign Application Priority Data
Mar. 30, 2005 (JP) 2005-097377

(51) Int. Cl. H01S 5/00; H01S 3/04

(52) U.S. Cl. 372/43.01

(57) ABSTRACT

On an n-type GaAs substrate 19 are formed an n-type GaAs buffer layer 20, a non-doped AlₓGa₁₋ₓAs light guide evaluation layer 21, an n-type AlₓGa₁₋ₓAs first clad layer 22, an n-type AlₓGa₁₋ₓAs second clad layer 23, a non-doped AlₓGa₁₋ₓAs first light guide layer 24, a non-doped AlₓGa₁₋ₓAs quantum well active layer 25, a non-doped AlₓGa₁₋ₓAs second light guide layer 26, a p-type AlₓGa₁₋ₓAs first clad layer 27, a p-type GaAs etching stop layer 28, a p-type AlₓGa₁₋ₓAs second clad layer 29 and a p-type GaAs cap layer 30. The Al crystal mixing ratio of the light guide evaluation layer 21 is equal to that of the first and second light guide layers 24, 26. The semiconductor laser device allows the control of layer thickness and material composition of the light guide layers to be fulfilled with simplicity and high precision.

### CROSS-REFERENCE TO RELATED APPLICATIONS

The present non-provisional application claims priority based on JP 2005-97377 applied for patent in Japan on Mar. 30, 2005 under U.S. Code, Volume 35, Chapter 119(a). The disclosure of the application is fully incorporated herein by reference.

### BACKGROUND OF THE INVENTION

The present invention relates to a semiconductor laser device and a manufacturing method therefor.

In recent years, the demand for semiconductor laser devices, which are center position semiconductor devices to be used in pickups for DVDs (Digital Versatile Discs) and CDs (Compact Discs), has been increasing more and more, the demand being directed toward semiconductor lasers having less variations in characteristic and high reliability.

Whereas the double heterojunction has been used as the basic structure for semiconductor laser devices, such multilayered structures as the SCH (Separate Confinement Heterostructure), in which a carrier confinement region and a light confinement region (light guide layer) are separated from each other, and the MQW (Multi Quantum Well) structure, in which quantum wells are formed in the active region, have been proposed in keeping up with demands for higher power of optical output or decreased threshold currents. In these multilayered structures, the smallest layer thickness is several tens to several hundreds of angstroms (Å), and MOCVD (Metal Organic Chemical Vapor Deposition) process or MBE (Molecular Beam Epitaxy) process, which allows easier control of layer thickness, and other vapor phase epitaxial processes have been used for the formation of semiconductor thin films instead of conventional liquid phase epitaxial processes.

For a method of reducing characteristic variations of semiconductor laser devices made by the vapor phase epitaxial processes, it is important to control each layer thickness or material composition of the multilayered structure. Generally, for crystal growth of such a multilayered structure as above-described semiconductor laser devices, the layers constituting the multilayered structure are grown layer by layer for each single layer as a preparatory step for the crystal growth of the multilayered structure, their layer thicknesses and material composition ratios are evaluated, and such growth conditions as growth time and gas flow rate are fed back to the multilayered structure. Further, even after the start of crystal growth of the multilayered structure, layer thicknesses and composition ratios of the individual layers constituting the multilayered structure are measured, differences from design values are adjusted, and the crystal growth of the next multilayered structure is performed.

The method for measuring the layer thickness may be a method of, with the wafer cleaved, observing a cross section of the stacked layers directly by a scanning electron microscope or the like, or a method of selectively etching a deposited layer and measuring a resulting step gap by a contact step gap meter, or the like. As to the evaluation of a material composition ratio, a targeted layer is subjected to photoluminescence measurement or X-ray diffraction measurement to identify the composition ratio.

A conventional semiconductor laser device is one described in JP 2003-60315 A.

In the method of manufacturing this conventional ridge-type semiconductor laser device, first, as shown in FIG. 1A, on an n-type GaAs substrate 1 are crystal grown one after another by the MOCVD process an n-type GaAs buffer layer 2 (layer thickness=0.5 μm), an n-type AlₓGa₁₋ₓAs first clad layer 3 (x=0.46, layer thickness=2.7 μm), an n-type AlₓGa₁₋ₓAs second clad layer 4 (x=0.48, layer thickness=0.2 μm), a non-doped AlₓGa₁₋ₓAs first light guide layer 5 (x=0.35, layer thickness=280 Å), a non-doped AlₓGa₁₋ₓAs quantum well active layer 6, a non-doped AlₓGa₁₋ₓAs second light guide layer 7 (x=0.35, layer thickness=280 Å), a p-type AlₓGa₁₋ₓAs first clad layer 8 (x=0.48, layer thickness=0.2 μm), a p-type GaAs etching stop layer 9 (layer thickness=26 Å), a p-type AlₓGa₁₋ₓAs second clad layer 10 (x=0.48, layer thickness=1.3 μm) and a p-type GaAs cap layer 11 (layer thickness=0.75 μm).

Next, as shown in FIG. 1B, resist 12 having a mask pattern that covers a specified region is formed by photolithography process or the like, and then the p-type GaAs cap layer 11 and the p-type AlₓGa₁₋ₓAs second clad layer 10 located on both sides of the specified region are partly removed by etching. As a result of this, the p-type GaAs cap layer 11 and the p-type AlₓGa₁₋ₓAs second clad layer 10 that have remained under the resist 12 constitute a ridge.

Next, after removal of the resist 12, an n-type AlₓGa₁₋ₓAs current blocking layer 13 (x=0.7, layer thickness=1.0 μm), an n-type GaAs current blocking layer 14 (layer thickness=0.3 μm) and a p-type GaAs planarization layer 15 (layer thickness=0.7 μm) are stacked one by one in order to constrict the current to within the ridge shape as shown in FIG. 1C.

Next, for removal of unnecessary portions formed on the ridge in the n-type AlₓGa₁₋ₓAs current blocking layer 13, the n-type GaAs current blocking layer 14 and the p-type GaAs planarization layer 15, resist is formed on their portions other than on the ridge by photolithography process, and the unnecessary portions are removed by etching.

Next, after removal of the resist, a p-type GaAs contact layer 16 (layer thickness=50 μm) is crystal grown on the ridge, the n-type AlₓGa₁₋ₓAs current blocking layer 13, the n-type GaAs current blocking layer 14 and the p-type GaAs planarization layer 15 as shown in FIG. 1D.

Finally, a p-side electrode 17 is formed on the p-type GaAs contact layer 16 while an n-side electrode 18 is formed on the n-type GaAs substrate 1, thus the semiconductor laser device being completed.

In this connection, semiconductor laser devices, which are light sources for optical discs, have been in progress toward higher output with a view to higher speeds of recording and reproduction. This makes it important for the semiconductor laser device to control the radiation angle for both reduction of variations in device characteristics and enhancement of repeatability of characteristics. The radiation angle in the vertical direction in the SCH-MQW structure that has been used for high-power semiconductor laser devices depends on the refractive index difference between active layer and clad layer and on the layer thickness or material composition ratio of the light guide layer that acts for light confinement.

In particular, when such a laser structure as shown in FIG. 1A is formed by continuous crystal growth, evaluating a completed laser structure and estimating deviations from design values in the wafer stage allows characteristics of the semiconductor laser device to be predicted. Moreover, correcting deviations from the design to normal values is an important technique for the reduction of variations in device characteristics and the enhancement of the repeatability.

For the clad layer, which is a comparatively large in layer thickness in the laser structure, its layer thickness can be evaluated by a method of directly observing a wafer cross section by a scanning electron microscope or a method of selectively etching a deposited layer and measuring a resulting step gap by a contact step gap meter, or the like.

Also, for the evaluation of the material composition ratio, the material composition ratio of a targeted layer can be measured by performing photoluminescence measurement or X-ray diffraction measurement on the targeted layer.

Also, for the evaluation of the multiquantum well active layer, there has been established a measurement of cyclic layer thickness utilizing satellite reflection of X-ray diffraction.

However, in the conventional semiconductor laser device described above, the light guide layer forming the active layer has a very thin design layer thickness, generally as small as several hundreds of angstroms (Å) or less, making it hard to measure the layer thickness or the composition ratio of the layers constituting the semiconductor laser device in the wafer stage.

The light guide layer, although being an important layer on which the radiation angle depends, can hardly be evaluated for its layer thickness or composition ratio in the wafer stage. Thus, with a view to for the reduction of variations in device characteristics and the enhancement of the repeatability, a simple measurement method is desired also for correction of any deviations from design values in the crystal growth.

In the case where the multilayered structure of a semiconductor laser device is formed by continuous crystal growth, checking of the layer thickness or composition ratio of the light guide layer is implemented by a process of subjecting the light guide layer into crystal growth in a single layer independent of the multilayered structure evaluating the layer thickness or composition ratio of the light guide layer, and feeding back evaluation results to the multilayered structure. This process would involve the need for crystal growth intended for checking of the light guide layer independent of the crystal growth of the multilayered structure of the semiconductor laser device, which leads to a need for performing additional crystal growth.

The evaluation of the light guide layer included in the multilayered structure of the semiconductor laser device, once having become practicable, makes it practicable to do characteristic prediction of the wafer itself in which the multilayered structure has been formed, where it becomes possible, for example, to execute non-defectiveness decision of characteristics at the wafer stage.

### SUMMARY OF THE INVENTION

Accordingly, an object of the present invention is to provide a semiconductor laser device, as well as a manufacturing method therefor, which allows the control of the layer thickness and material composition of the light guide layer to be carried out with simplicity and high precision.

In order to achieve the above object, there is provided a semiconductor laser device comprising:
an active layer;
a light guide layer for confining light emitted by the active layer; and
a light guide evaluation layer having a material composition identical to that of the light guide layer.

In this semiconductor laser device, the evaluation of layer thickness of the light guide evaluation layer can be achieved, for example, by observing a cross section of the wafer including the light guide evaluation layer by means of a scanning electron microscope, or by selectively etching the wafer and measuring a step gap resulting from the selective etching by means of a contact step gap meter.

Also, the growth rate of the light guide layer can be determined by dividing the layer thickness of the light guide evaluation layer by its growth time.

Also, the layer thickness of the light guide layer to be grown for the growth time can be estimated by multiplying the growth time of the light guide layer by the above growth rate.

Also, the evaluation of the material composition of the light guide evaluation layer can be achieved by using a photoluminescence or X-ray diffraction method. Based on the evaluation result, the material composition of the light guide layer can be estimated.

Since the layer thickness and material composition of the light guide evaluation layer can be evaluated as described above, simple, high-precision control of layer thickness and material composition over the light guide layer can be achieved based on the evaluation result.

In one embodiment of the present invention, the semiconductor laser device further comprises a clad layer which is located between the light guide evaluation layer and the active layer.

In this embodiment, since the semiconductor laser device includes a clad layer located between the light guide evaluation layer and the active layer, it is unlikely that the light guide evaluation layer adversely affects optical characteristics of the active layer.

In addition, it is undesirable to form the light guide evaluation layer on the second-conductive-type upper clad layer because the light guide evaluation layer could not be formed into a ridge shape by the conventional ridge formation method.

In one embodiment, the semiconductor laser device comprises:
a substrate formed under the light guide evaluation layer;
a first-conductive-type lower clad layer formed between the light guide evaluation layer and the active layer; and
a second-conductive-type upper clad layer formed on the active layer.

The first conductive type refers to p type or n type. Also, the second conductive type refers to n type when the first conductive type is the p type, and refers to p type when the first conductive type is the n type.

In one embodiment of the present invention, a layer thickness of the light guide evaluation layer is larger than a layer thickness of the light guide layer.

In the semiconductor laser device of this embodiment, since the layer thickness of the light guide evaluation layer is larger than that of the light guide layer, the evaluation of layer thickness and composition ratio for the light guide evaluation layer can be achieved with simplicity and high precision.

In one embodiment of the present invention, a manufacturing method for manufacturing the above semiconductor laser device comprises the step of:
measuring a material composition of the light guide evaluation layer and controlling growth conditions for the light guide layer based on a measurement result of the material composition of the light guide evaluation layer.

In this semiconductor laser device manufacturing method, since the method includes the steps of measuring a material composition of the light guide evaluation layer and controlling growth conditions for the light guide layer based on a measurement result of the material composition of the light guide evaluation layer, the material composition of the light guide layer can be made closer to design values. Thus, a semiconductor laser device which is smaller in characteristic variations can be manufactured with good repeatability.

In one embodiment of the present invention, the manufacturing method for manufacturing the above semiconductor laser device comprises the step of:
measuring a thickness of the light guide evaluation layer and controlling growth conditions for the light guide layer based on a measurement result of the layer thickness of the light guide evaluation layer.

In this semiconductor laser device manufacturing method, since the method includes the steps of measuring a thickness of the light guide evaluation layer and controlling growth conditions for the light guide layer based on a measurement result of the thickness of the light guide evaluation layer, the thickness of the light guide layer can be made closer to design values. Thus, a semiconductor laser device which is smaller in characteristic variations can be manufactured with good repeatability.

According to the semiconductor laser device of the present invention, by virtue of the arrangement that a light guide evaluation layer having a material composition identical to that of the light guide layer is formed outside the active layer including the light guide layer, it becomes implementable to evaluate layer thickness and material composition of the light guide evaluation layer and, based on the evaluation result, exert the control of layer thickness and material composition over the light guide layer with simplicity and high precision.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1A is a manufacturing process diagram of a semiconductor laser device according to a prior art;

FIG. 1B is a manufacturing process diagram of a semiconductor laser device according to a prior art;

FIG. 1C is a manufacturing process diagram of a semiconductor laser device according to a prior art;

FIG. 1D is a manufacturing process diagram of a semiconductor laser device according to a prior art;

FIG. 2A is a manufacturing process diagram of a semiconductor laser device which is an embodiment of the present invention;

FIG. 2B is a manufacturing process diagram of a semiconductor laser device which is an embodiment of the present invention;

FIG. 2C is a manufacturing process diagram of a semiconductor laser device which is an embodiment of the present invention;

FIG. 2D is a manufacturing process diagram of a semiconductor laser device which is an embodiment of the present invention.

### DETAILED DESCRIPTION OF THE PREFERRED EMBODIMENTS

Hereinbelow, a semiconductor laser device and a manufacturing method therefor of the present invention will be described in detail by way of embodiment thereof illustrated in the accompanying drawings.

A manufacturing example of the SCH-MQW semiconductor laser device, which has an emission wavelength of 780 to 786 nm and which is formed of an AlGaAs-based material is described in this embodiment.

Manufacturing process of this SCH-MQW semiconductor laser device includes a step of crystal growth by MOCVD process. However, before doing this crystal growth, there is a need for determining the growth rate and Al crystal mixing ratio of the guide layer, the AlGaAs clad layer, the GaAs cap layer and the like to be formed.

First, the method of determining the growth rate of the non-doped AlGaAs light guide layer, the n-type AlGaAs clad layer, the p-type AlGaAs clad layer and the p-type GaAs cap layer is explained. As an example, after the clad layer and the cap layer are deposited to about 1 μm, a their layer thickness is determined by directly observing their cross section by a scanning electron microscope, and a growth rate is calculated from the growth time.

The Al crystal mixing ratio can be determined by the X-ray diffraction method from a wafer in which layers to be measured have been deposited to about 1 μm.

Based on the growth rate determined by such a method as described above, growth time for each layer is determined so as to meet a specified design layer thickness. Also for the Al crystal mixing ratio, the gas flow rate is corrected in consideration of deviations from design values.

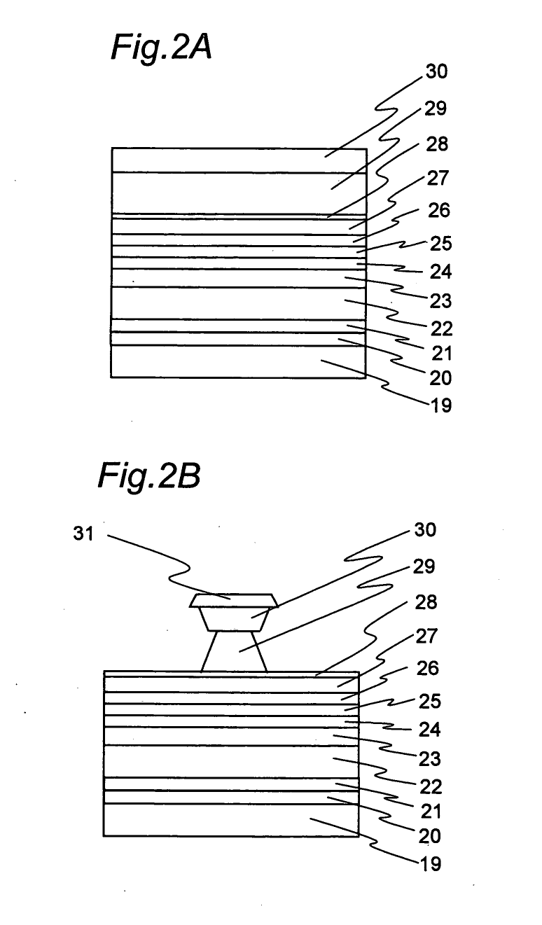

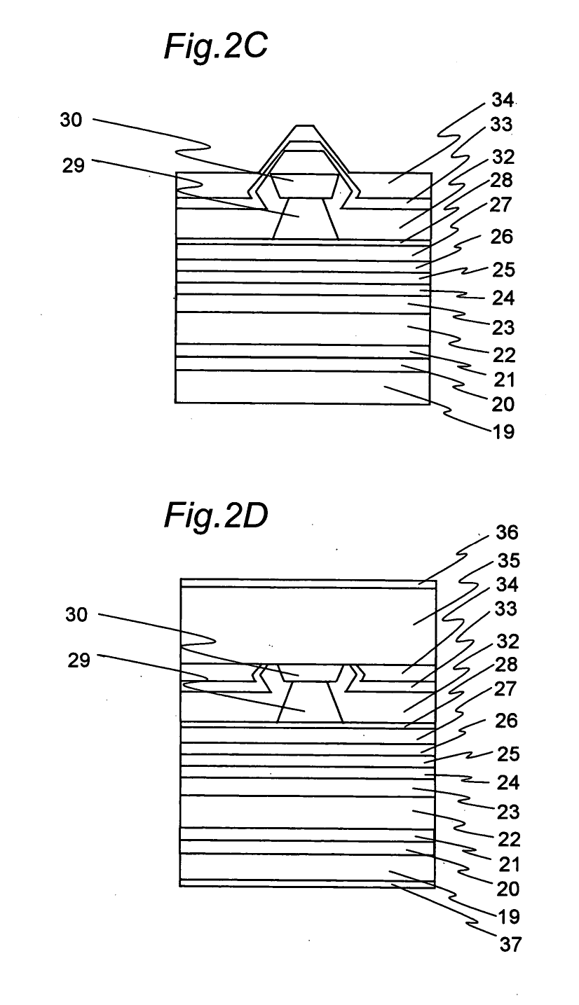

In the manufacturing method of this SCH-MQW semiconductor laser device, first, as shown in FIG. 2A, on an n-type GaAs substrate 19 are crystal grown one after another by the MOCVD process an n-type GaAs buffer layer 20 (layer thickness=0.5 μm), a non-doped AlₓGa₁₋ₓAs light guide evaluation layer 21 (x=0.35, layer thickness=0.4 μm), an n-type AlₓGa₁₋ₓAs first clad layer 22 (x=0.46, layer thickness=2.7 μm), an n-type AlₓGa₁₋ₓAs second clad layer 23 (x=0.48, layer thickness=0.2 μm), a non-doped AlₓGa₁₋ₓAs first light guide layer 24 (x=0.35, layer thickness=280 Å), a non-doped AlₓGa₁₋ₓAs quantum well active layer 25, a non-doped AlₓGa₁₋ₓAs second light guide layer 26 (x=0.35, layer thickness=280 Å), a p-type AlₓGa₁₋ₓAs first clad layer 27 (x=0.48, layer thickness=0.2 μm), a p-type GaAs etching stop layer 28 (layer thickness=26 Å), a p-type AlₓGa₁₋ₓAs second clad layer 29 (x=0.48, layer thickness=1.3 μm) and a p-type GaAs cap layer 30 (layer thickness=0.75 μm).

The Al crystal mixing ratio of the light guide evaluation layer 21 is set so as to be equal to that of the first and second light guide layers 24, 26.

Also, the layer thickness of the light guide evaluation layer 21 is set to a value larger than that of the first and second light guide layers 24, 26, so that cross-sectional observation by scanning electron microscope or Al crystal mixing ratio measurement by the X-ray diffraction method can be fulfilled. The layer thickness of the light guide evaluation layer 21 can be determined by cleaving the wafer, which has the multilayered structure shown in FIG. 2A, and directly observing a cross section of the wafer by a scanning electron microscope.

Also, a growth rate for the first and second light guide layers 24, 26 can be determined by dividing the layer thickness of the light guide evaluation layer 21 by the growth time of the light guide evaluation layer 21.

Now that the growth time of the first and second light guide layers 24, 26 is already known, a final grown layer thickness of the light guide layers can be estimated by multiplying the growth rate of the light guide evaluation layer 21 by the growth time of the first and second light guide layers 24, 26 determined as described above.

As to the Al crystal mixing ratio of the first and second light guide layers 24, 26 can be determined by etching the surface of the wafer so that the first and second light guide layers 24, 26 are exposed, and then applying the X-ray diffraction method or the like to the first and second light guide layers 24, 26.

Using the method described above makes it possible to evaluate layer thickness and composition deviations of the first and second light guide layers 24, 26. Thus, it becomes implementable to make decisions as to non-defectiveness of the wafer.

Also, in the case where continuous crystal growth is performed, deviations from design values, if any, can be corrected based on the above evaluation results.

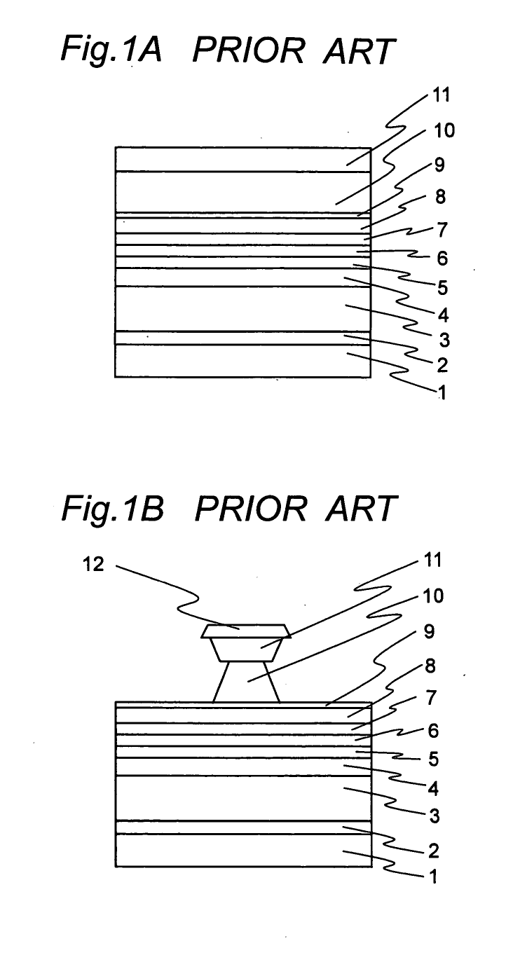

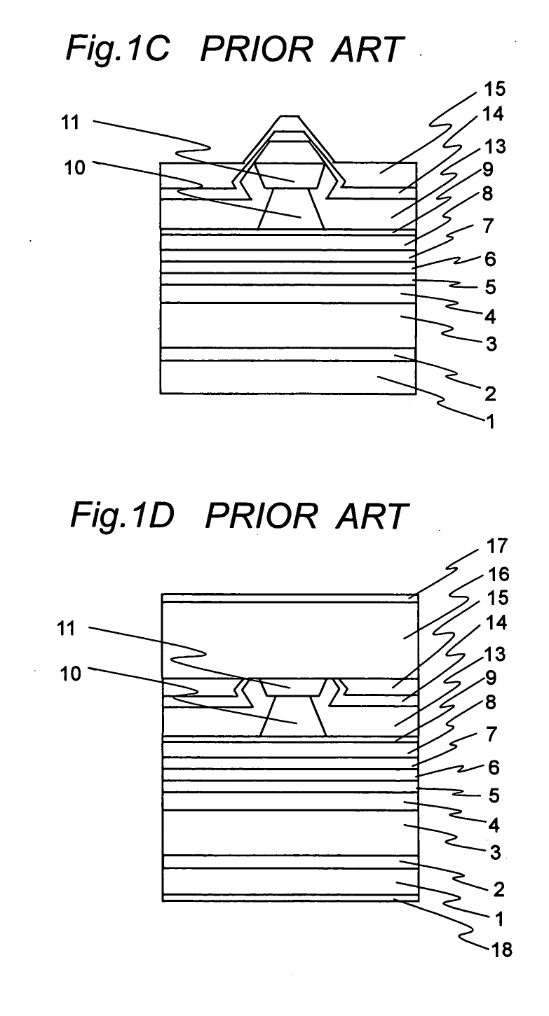

Next, processes subsequent to the crystal growth of FIG. 1A are explained.

On the cap layer 30, as shown in FIG. 2B, resist 31 having a striped mask pattern is formed by photolithography process or the like, and then the cap layer 30 and the second clad layer 29 located on both sides of the mask pattern are partly removed by using a sulfuric-acid based etchant and hydrofluoric acid. As a result of this, the cap layer 30 and the second clad layer 29 that have remained under the resist 31 constitute a ridge.

Next, after removal of the resist 31, an n-type AlₓGa₁₋ₓAs current blocking layer 32 (x=0.7, layer thickness=1.0 μm), an n-type GaAs current blocking layer 33 (layer thickness=0.3 μm) and a p-type GaAs planarization layer 34 (layer thickness=0.7 μm) are crystal grown by MOCVD process as shown in FIG. 2C.

Next, for removal of unnecessary layer deposited on the ridge, resist is formed on portions other than on the ridge by photolithography process, and the unnecessary layers are removed by etching with an ammonia- and sulfuric acid-based etchant.

Next, after removal of the resist, a p-type GaAs contact layer 35 (layer thickness=50 μm) is crystal grown by MOCVD process as shown in FIG. 2D.

After the wafer is made 100 μm thick by polishing or etching applied onto the substrate surface of the wafer that has been completely crystal grown up to the contact layer 35 as shown above, a p-side electrode 36 is formed on the p-side surface of the wafer while an n-side electrode 37 is formed on the n-side surface of the wafer. Then, a cleavage division is formed in a bar-like shape vertical to the ridge stripe, and both output surfaces are coated with an insulating film, thus the semiconductor laser device being completed.

The SCH-MQW semiconductor laser device formed from AlGaAs based materials as in this manufacturing method allows an easy evaluation of layer thickness and composition ratio of the first and second light guide layers 24, 26 by the wafer having a multilayered laser structure. Thus, it becomes implementable to manufacture the semiconductor laser device with good repeatability.

In this embodiment, the n-type GaAs substrate 19 is an example of the substrate, the non-doped AlₓGa₁₋ₓAs light guide evaluation layer 21 is an example of the light guide evaluation layer, the n-type AlₓGa₁₋ₓAs first clad layer 22 and the n-type AlₓGa₁₋ₓAs second clad layer 23 are an example of the clad layers, the first and second light guide layers 24, 26 are an example of the light guide layers, and the non-doped AlₓGa₁₋ₓAs quantum well active layer 25 is an example of the active layer.

In this embodiment, on an n-type substrate are formed a non-doped light guide evaluation layer, an n-type lower clad layer, a non-doped light guide layer, a non-doped active layer, a non-doped light guide layer and a p-type upper clad layer. However, on a p-type substrate, a non-doped light guide evaluation layer, a p-type lower clad layer, a non-doped light guide layer, a non-doped active layer, a non-doped light guide layer and an n-type upper clad layer may be formed. That is, the conductive type of the embodiment may be reversed in all. However, the non-doped layers should remain as they are non-doped layers.

The present invention is applicable not only to semiconductor laser devices formed from AlGaAs based materials but also to, for example, semiconductor laser devices formed from AlGaInP based materials or the like to be used for red lasers. That is, the materials of the semiconductor laser device of the present invention are not limited to those of the above embodiment.

Further, the present invention is applicable not only to semiconductor laser devices of double heterostructure and manufacturing methods therefor but also to semiconductor laser devices of single heterostructure and manufacturing methods therefor.

Although the present invention has been described as above, it is obvious that the present invention can be modified by a variety of methods. Such modifications are not regarded as departing from the spirit and scope of the present invention, and it is appreciated that improvements apparent to those skilled in the art are fully included within the scope of the following claims.

1. A semiconductor laser device comprising:
an active layer;
a light guide layer for confining light emitted by the active layer; and
a light guide evaluation layer having a material composition identical to that of the light guide layer.

2. The semiconductor laser device as claimed in claim 1, further comprising
a clad layer which is located between the light guide evaluation layer and the active layer.

3. The semiconductor laser device as claimed in claim 1, wherein
a layer thickness of the light guide evaluation layer is larger than a layer thickness of the light guide layer.

4. A manufacturing method for manufacturing the semiconductor laser device as defined in claim 1, comprising the step of:
measuring a material composition of the light guide evaluation layer and controlling growth conditions for the light guide layer based on a measurement result of the material composition of the light guide evaluation layer.

5. A manufacturing method for manufacturing the semiconductor laser device as defined in claim 1, comprising the step of:
measuring a thickness of the light guide evaluation layer and controlling growth conditions for the light guide layer based on a measurement result of the layer thickness of the light guide evaluation layer.
